(19) United States
(12) Patent Application Publication
(10) Pub. No.: US 2010/0158645 A1
(43) Pub. Date: Jun. 24, 2010

(54) Stage apparatus

(75) Inventor: Fuminori Makino, Yokosuka-shi (JP)

Correspondence Address: SQUIRE, SANDERS & DEMPSEY L.L.P., 8000 TOWERS CRESCENT DRIVE, 14TH FLOOR, VIENNA, VA, 22182-6212, US

(73) Assignee: Sumitono Heavy Industries, Ltd.

(21) Appl. No.: 12/318,252

(22) Filed: Dec. 23, 2008

(51) Int. Cl. H01L 21/677

(52) U.S. Cl. 414/222.07

(57) ABSTRACT

The present invention enables a movable body to be moved without generating pitching. X-axis drive parts, which have: X-axis shafts formed by disposing a plurality of magnets along an X-axis direction and connected to a pair of Y-axis movers; and X-axis movers constituted by coils surrounding the X-axis shafts, are respectively arranged on both outer sides of an X-axis movable body, thereby making it possible to adjust the position of the X-axis movable body in the vertical direction. Then, lowering the position of the X-axis movable body in the vertical direction brings the center of gravity location of the X-axis movable body in the vertical direction in proximity to the X-axis shafts and Y-axis drive parts having Y-axis movers. Consequently, the X-axis movable body is stabilized and supported by the X-axis drive parts.

### BACKGROUND OF THE INVENTION

1. Field of the Invention

The present invention relates to a stage apparatus for moving a movable body in the XY directions on a base.

2. Related Background Art

Conventionally, a stage apparatus, which comprises a pair of stators (Y-axis shafts) that respectively extend along the Y-axis direction on both sides of a base member (base), a pair of movers (Y-axis movers) that are respectively driven in the Y-axis direction in accordance with electromagnetic interaction with the pair of stators, and a wafer drive device that is suspended between these movers, this wafer drive device having a stator (X-axis shaft), which extends along the X-axis direction and is connected to the above-mentioned movers and a mover (X-axis mover), which is driven in the X-axis direction in accordance with electromagnetic interaction with the stator, and a wafer stage (movable body), which sits atop the mover for driving in the X-axis direction, wherein respectively driving the movers in the X-axis direction and the Y-axis direction drives the wafer stage biaxially, is known (For example, refer to Japanese Patent Application Laid-open No. 2001-23894).

However, the problem with the above-described stage apparatus is that up-down vibration (pitching) occurs in the axial direction of the X-axis shaft when the wafer stage moves.

### SUMMARY OF THE INVENTION

An object of the present invention, which is constituted to solve this problem, is to provide a stage apparatus that makes it possible to move the movable body, which is the wafer stage, without generating pitching.

A stage apparatus related to the present invention has a pair of Y-axis stators, which are fixed to the top surface of a base and extend in the Y-axis direction, a pair of Y-axis movers that move along the respective Y-axis stators, a shaft motor having an X-axis shaft, which extends in an X-axis direction that is orthogonal to the Y-axis direction and is connected to the pair of Y-axis movers, and an X-axis mover, which is constituted by a coil that surrounds this X-axis shaft, and a movable body that moves over the base, and is characterized in that the X-axis mover is connected to the side of the movable body. According to a stage apparatus like this, since the X-axis mover is arranged on the side of the movable body, it is possible to lower the location of the movable body downwardly in the vertical direction compared to the prior art, wherein the movable body rests atop the X-axis mover, making it possible to bring the center of gravity location of the movable body closer to the height location of the shaft motor having the X-axis shaft and the X-axis mover. Consequently, the movable body can be stabilized and supported by the shaft motor, making it possible to move the movable body without generating pitching. Further, since the X-axis mover is disposed on the inside directly beneath a table in the prior art, the X-axis mover comes into close proximity to the location of the wafer at times and adversely affects this wafer by making it easier for heat to be transferred to sites that demand precision. Further, disposing the X-axis mover inside also increases the risk of heat buildup. By contrast, according to the stage apparatus related to the present invention, providing the X-axis mover on the side of the movable body makes it possible to distance the X-axis mover from the wafer location, enabling a constitution in which there is no heat buildup.

Further, it is preferable that the shaft motor be provided in a pair, and that the pair of shaft motors be respectively arranged on both outer sides of the movable body. Consequently, it is possible to stably move the movable body in accordance with applying thrust from both outer sides of the movable body.

Further, it is preferable that the stage apparatus of the present invention have a guidebeam, which is connected to the pair of Y-axis movers, is positioned on the inner side of the movable body, and extends in the X-axis direction, and that the movable body have a lateral part, which faces the side of the guidebeam, and a pair of first air bearings, which are disposed on the lateral part, and blow air on the side of the guidebeam. Consequently, since the X-axis shaft and X-axis mover are respectively arranged on the outer side of the lateral part of the movable body, the movable body can be made smaller and lighter weight than when the X-axis shaft and X-axis mover are arranged in the inner side of the movable body.

Further, it is preferable that the movable body have a second air bearing that blows air on the top surface of the base. Consequently, the top surface of the base can be treated as a gliding surface, making it possible to move the movable body while supporting same in a non-contact state. Furthermore, the air bearing not only blows air, but can also have a suction function.

Further, it is preferable that the height of the center of gravity of the movable body coincide with the heights of the center of the shafts of the X-axis shaft and X-axis mover. Consequently, it is possible to further stabilize and support the movable body with the X-axis drive part, making it possible to move the movable body without generating pitching.

### BRIEF DESCRIPTION OF THE DRAWINGS

FIG. 1 is an oblique view showing a stage apparatus related to an embodiment of the present invention;

FIG. 2 is a plan view of the stage apparatus shown in FIG. 1;

FIG. 3 is a side view of the stage apparatus shown in FIG. 1;

FIG. 4 is a cross-sectional view along line IV-IV of FIG. 3;

FIG. 5 is an enlarged view of the lateral part of the Y-axis movable body in FIG. 1 as seen from the Y-axis direction.

### DESCRIPTION OF THE PREFERRED EMBODIMENTS

The preferred embodiment of a stage apparatus according to the present invention will be explained below while referring to the attached drawings.

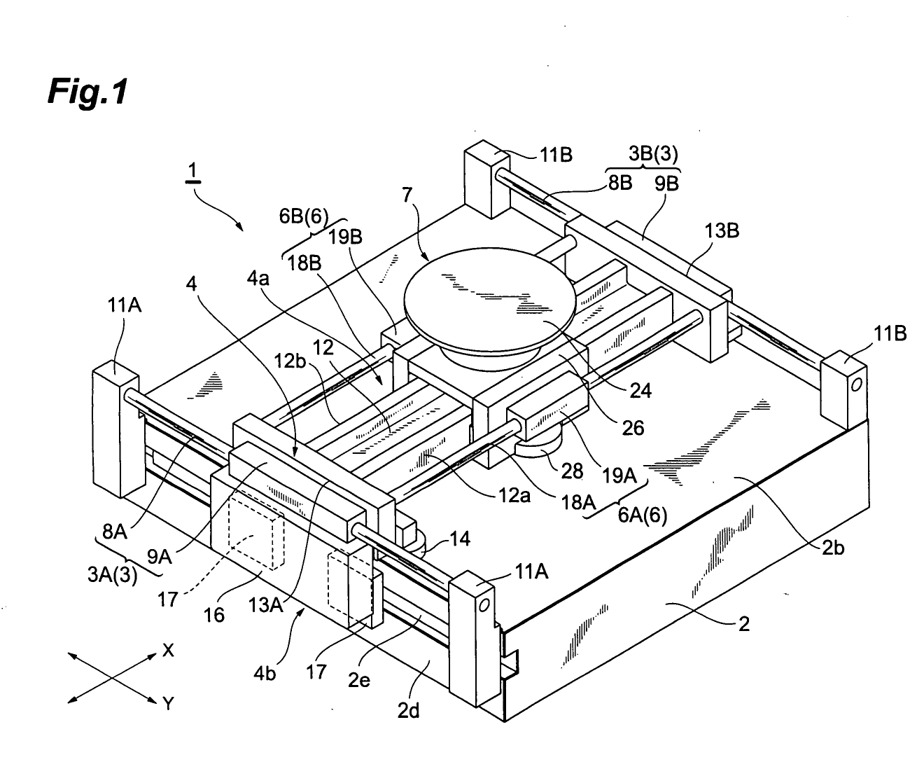

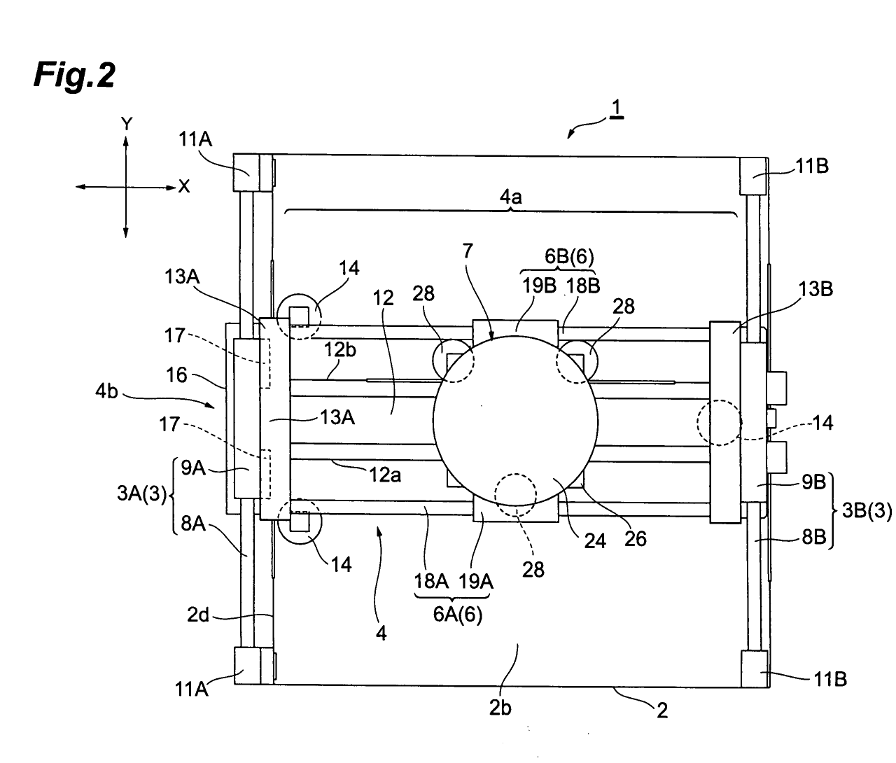

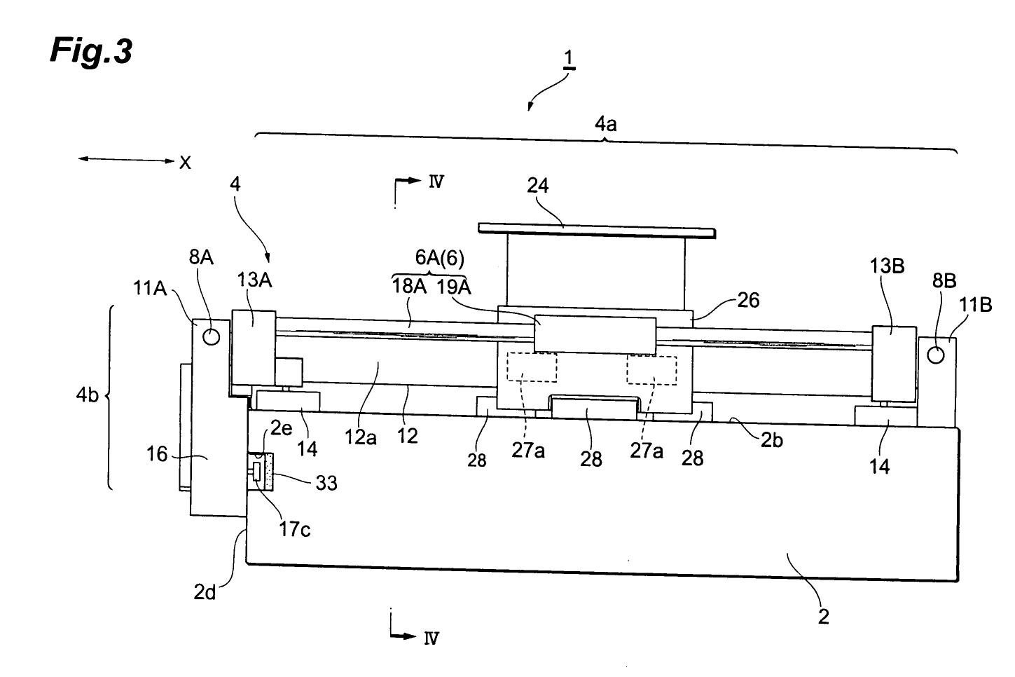

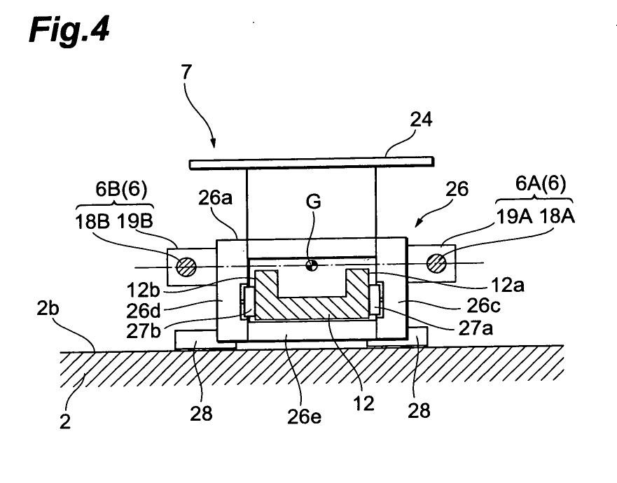

FIG. 1 is an oblique view showing a stage apparatus related to the embodiment of the present invention, FIG. 2 is a plan view of the stage apparatus shown in FIG. 1, FIG. 3 is a side view of the stage apparatus shown in FIG. 1, and FIG. 4 is a cross-sectional view along line IV-IV of FIG. 3.

As shown in FIG. 1, a stage apparatus 1 comprises a base 2; a Y-axis drive part 3 comprising a pair of Y-axis shaft motors 3A, 3B; a Y-axis movable body 4 that is moved in the Y-axis direction by the Y-axis drive part 3; an X-axis drive part 6 comprising a pair of X-axis shaft motors 6A, 6B disposed on the Y-axis movable body 4; and an X-axis movable body (movable body) 7 that is moved in the X-axis direction by the X-axis drive part 6. Furthermore, in the drawing, the direction in which the X-axis shaft motors 6A, 6B extend is the X-axis direction, and the horizontal direction that is orthogonal to the X-axis direction is the Y-axis direction.

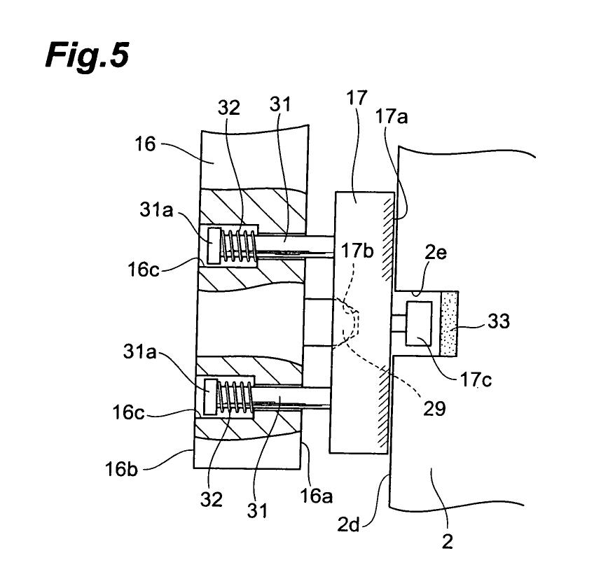

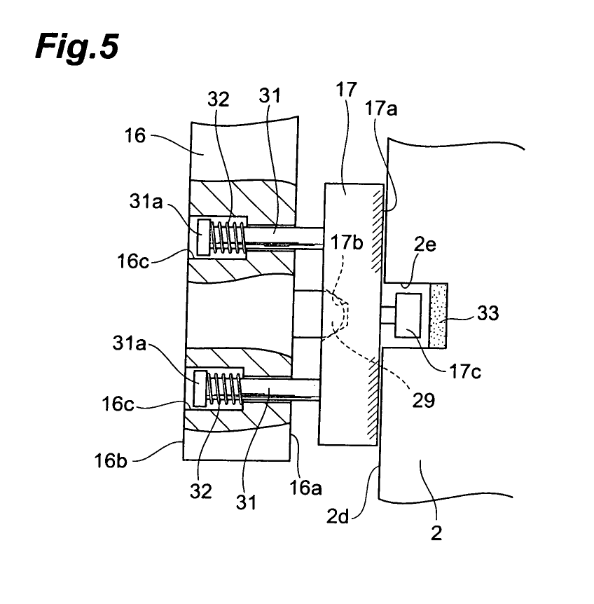

The base 2 is made from a rectangular plate-like stone material, and a top gliding surface (top surface) 2b on which the air bearing glides is formed on the top surface thereof by carrying out planar processing. Further, of the sides extending along the Y-axis direction, a side gliding surface 2d on which the air bearing glides is also formed on the one side by carrying out the same planar processing as that done on the top surface. A groove part 2e extending along the Y-axis direction is formed in this side gliding surface 2d. A magnetic body 33 extending along the Y-axis direction is disposed inside this groove part 2e (Refer to FIG. 5).

The Y-axis shaft motors 3A, 3B constituting the Y-axis drive part 3 comprise a pair of Y-axis shafts (Y-axis stators) 8A, 8B extending along the Y-axis direction that have magnets built inside them, and Y-axis movers 9A, 9B disposed so as to surround portions of the Y-axis shafts 8A, 8B extending axially.

As shown in FIGS. 1 and 2, the Y-axis shafts 8A, 8B are formed by respectively disposing a plurality of magnets along the Y-axis direction upwardly and on both sides of the base 2 in the X-axis direction. These magnets are joined together north pole to north pole and south pole to south pole, and these joined magnets are lined up side by side in a row arrangement. The Y-axis shaft 8A on the side of the side gliding surface 2d is held at both ends by a pair of holding members 11A respectively fixed longitudinally at both sides of the side gliding surface 2d, and are arranged on the outer side of the base 2 as seen from above. Similarly, the other Y-axis shaft 8B is also held at both ends by a pair of holding members 11B arranged in a standing position on the base 2.

The Y-axis movers 9A, 9B are respectively constituted by placing coils that surround the Y-axis shafts 8A, 8B inside housings. The Y-axis movers 9A, 9B respectively move in the Y-axis direction in accordance with electromagnetic interaction generated by running electric current through the coils to create electromagnetic forces with the Y-axis shafts 8A, 8B, which comprise magnets.

As shown in FIGS. 1 through 3, the Y-axis movable body 4 has a main body part 4a facing the top gliding surface 2b of the base 2 and a lateral part 4b facing the side gliding surface 2d. The main body part 4a and lateral part 4b are constituted from different components, making for ease of manufacture and maintenance. The main body part 4a of the Y-axis movable body 4 comprises an X-axis drive part 6; a guidebeam 12 connected to the Y-axis movers 9A, 9B for guiding the X-axis mover 7; and a Y-axis lift air bearing 14 for supporting the Y-axis mover 4 in the up-down direction.

The X-axis shaft motors 6A, 6B constituting the X-axis drive part 6 comprise a pair of X-axis shafts 18A, 18B extending along the X-axis direction that have magnets on the inside; and X-axis movers 19A, 19B disposed so as to surround portions of the X-axis shafts 18A, 18B extending axially.

The X-axis shafts 18A, 18B are formed by disposing a plurality of magnets along the X-axis direction, and are connected to the Y-axis movers 9A, 9B by way of support members 13A, 13B. These magnets are joined together north pole to north pole and south pole to south pole, and these joined magnets are lined up side by side in a row arrangement.

The X-axis movers 19A, 19B are respectively constituted by placing coils that surround the X-axis shafts 18A, 18B inside housings. The X-axis movers 19A, 19B respectively move in the X-axis direction in accordance with electromagnetic interaction generated by running electric current through the coils to create electromagnetic forces with the X-axis shafts 18A, 18B, which comprise magnets.

The guidebeam 12 has a cross-sectional U-shape that is open towards the top as shown in FIGS. 1 through 4, and gliding surfaces 12a, 12b for the air bearing to glide on are formed by subjecting the outer sides of both sides extending along the X-axis direction to planar processing. Further, the guidebeam 12 is arranged between the X-axis shaft 18A and the X-axis shaft 18B as seen from above, is positioned so as to be housed on the inner side of a rectangle-shaped annular X-axis movable body 7, and is respectively connected to the Y-axis movers 9A, 9B at both ends in the longitudinal direction thereof by way of support members 13A, 13B.

Two Y-axis lift air bearings 14 are disposed at the ends of the Y-axis movable body 4 separated in the Y-axis direction on the lateral part 4b side of the main body part 4a, and one Y-axis lift air bearings 14 is disposed in the center of the Y-axis movable body 4 at the other end of the main body part 4a, and support the Y-axis movable body 4 in a non-contact state while providing a gap of around several micrometers between the Y-axis movable body 4 and the top gliding surface 2b by blowing air or another such gas onto the top gliding surface 2b to generate a repulsive force that balances the downward force resulting from the weight Y-axis movable body 4 itself. Furthermore, the air bearing does not only blow air, but can also have a suction function.

As shown in FIGS. 1 through 4, the X-axis movable body 7 comprises a rectangle-shaped annular moving member 26 surrounding the guidebeam 12; and a stage 24, which is disposed on the top of the moving member 26, and on which a wafer or the like is placed. As shown in FIG. 4, the moving member 26 has lateral parts 26c, 26d facing the gliding surfaces 12a, 12b of the guidebeam 12, and the surface of the outer side of lateral part 26c is connected to X-axis mover 19A, the surface of the outer side of lateral part 26d is connected to X-axis mover 19B, and the moving member 26 moves together with the X-axis movers 19A, 19B. Thus, the physical relationship between the X-axis movable body 7 and the X-axis drive part 6 is a relationship in which the X-axis shafts 18A, 18B and X-axis movers 19A, 19B are respectively arranged in both outer sides of the X-axis movable body 7. Further, the height of the gravitational center G of the X-axis movable body 7 coincides with the heights of the shaft centers of the X-axis shafts 18A, 18B and the X-axis movers 19A, 19B.

The X-axis movable body 7 respectively comprises on the inner sides of the lateral parts 26c, 26d of the moving member 26 two each X-axis yaw air bearings (first air bearings) 27a, 27b for blowing air on gliding surfaces 12a, 12b (Refer to FIG. 3). Further, the X-axis movable body 7 comprises three X-axis lift air bearings (second air bearings) 28 on the side of the bottom surface 26e of the moving member 26 for blowing air on the top gliding surface 2b of the base 2 (Refer to FIG. 2). Two are disposed separated in the X-axis direction on lateral part 26d, and one is disposed in the center of lateral part 26c in the X-axis direction. The X-axis yaw air bearings 27a, 27b support the X-axis movable body 7 in a non-contact state while providing gaps of around several micrometers between the X-axis movable body 7 and the gliding surfaces 12a, 12b by balancing the repulsive forces from the gliding surfaces 12a, 12b of the guidebeam 12 with one another. Further, the X-axis lift air bearings 28 support the X-axis movable body 7 in a non-contact state while respectively providing gaps of around several micrometers between the X-axis movable body 7 and the top gliding surface 2b of the base 2 by balancing the repulsive force from the top gliding surface 2b of the base 2 with the downward force resulting from the weight of the X-axis movable body 7 itself.

FIG. 5 is an enlarged view of the lateral part of the Y-axis movable body in FIG. 1 as seen from the Y-axis direction. As shown in FIGS. 1 and 5, the lateral part 4b of the Y-axis movable body 4 comprises a support part 16, which is disposed on the bottom surface of the Y-axis mover 9A and faces the side gliding surface 2d of the base 2. Further, the outer side of the lateral part 4b supports two flat plate-like Y-axis yaw air bearings (air bearings, refer to FIG. 1) 17 lined up side by side in the Y-axis direction for blowing air from blowing surfaces 17a facing the side gliding surface 2d toward the side gliding surface 2d as shown in FIG. 5. The Y-axis yaw air bearings 17 are rotatably supported by the support part 16. An air supply duct not shown in the drawing is connected to the Y-axis yaw air bearing 17, and air is supplied from an external supply device.

A spherically-shaped part 29, which has a spherical shape at the tip and makes contact with the back surface of the Y-axis yaw air bearing 17 is disposed in the face 16a of the Y-axis yaw air bearing 17 side of the support part 16. Further, a plurality of concave parts 16c is disposed around the spherically-shaped part 29 in the face 16b on the opposite side of face 16a, and the concave part 16c is open to the face 16a side in accordance with a throughhole disposed in the support part 16. Then, a pin 31 provided in a protruding condition on the back surface of the Y-axis yaw air bearing 17 is arranged so as to enter inside the concave part 16c through this throughhole. Further, a concave part 17b, which is tapered to become narrower toward the side of the blowing surface 17a, is disposed in the central part of the back surface of the Y-axis yaw air bearing 17, and the spherically-shaped part 29 enters into this concave part 17b. Then, an expandable spring 32 is arranged in a compressed state between the bottom of the concave part 16c of the support part 16 and a flange-shaped end part 31a of the pin 31, and the spring 32 thereby imparts elasticity in the opposite direction of the side gliding surface 2d. Consequently, a force pressing on the spherically-shaped part 29 is imparted by the Y-axis yaw air bearing 17, and the Y-axis yaw air bearing 17 is supported by the support part 16 at a desired pressure by way of the concave part 17b and the spherically-shaped part 29.

Further, a magnet 17c protruding toward the inside of the groove part 2e formed in the side gliding surface 2d is disposed in the central part of the blowing surface 17a. The magnet 17c generates an attraction force with a magnetic body 33 extending along the Y-axis direction at the bottom of the groove part 2e of the side gliding surface 2d. Furthermore, the gap between the magnet 17c and the magnetic body 33 is adjusted by adjusting the amount of protrusion of the magnet 17c, consequently balancing the repulsive force of the Y-axis yaw air bearing 17 and the attraction force of the magnet 17c, and adjusting the gap between the Y-axis yaw air bearing 17 and the side gliding surface 2d.

In the stage apparatus 1 constituted like the above, it is possible to freely move the stage 24 of the X-axis movable body 7 biaxially in accordance with the movements of the Y-axis movable body 4 and X-axis movable body 7 in line with the driving of the Y-axis drive part 3 and the X-axis drive part 6.

Then, according to the stage apparatus 1 of this embodiment, since a pair of X-axis shafts 18A, 18B and X-axis movers 19A, 19B constituting an X-axis movable body 7 and X-axis drive part 6 are respectively arranged on both outer sides of the X-axis movable body 7, the position of the X-axis movable body 7 can be lowered downwardly in the vertical direction, making it possible to bring the gravitational center location of the X-axis movable body 7 in closer proximity to the height location of the X-axis drive part 6 having the X-axis shafts 18A, 18B and X-axis movers 19A, 19B than in the prior art in which the X-axis movable body is placed on top of the X-axis mover. Consequently, it is possible to stabilize and support the X-axis movable body 7 with the X-axis drive part 6, making it possible to move the X-axis movable body 7 without generating pitching. Further, in the prior art, the X-axis mover is disposed on the inside directly beneath the table, so that the X-axis mover comes into close proximity to the location of the wafer at times and adversely affects this wafer by making it easier for heat to be transferred to sites that demand precision. Further, disposing the X-axis mover inside also increases the risk of heat buildup. By contrast, according to the stage apparatus 1 related to this embodiment, disposing the X-axis movers 19A, 19B on the sides of the X-axis movable body 7 makes it possible distance the X-axis movers 19A, 19B from the wafer location, enabling a constitution in which there is no heat buildup. Further, by there being a pair of shaft motors 6A, 6B, and by this pair of shaft motors 6A, 6B being respectively arranged on both outer sides of the X-axis movable body 7, it is possible to stably move the X-axis movable body 7 in accordance with applying thrust from both outer sides of the X-axis movable body 7.

Further, since the pair of X-axis shafts 18A, 18B and X-axis movers 19A, 19B are respectively arranged on the outer sides of the lateral parts 26c, 26d of the moving member 26 of the X-axis movable body 7, the X-axis movable body 7 can be made smaller and lighter in weight than when the pair of X-axis shafts 18A, 18B and X-axis movers 19A, 19B are respectively arranged on the inner side of the X-axis movable body 7.

Further, since the height of the gravitational center G of the X-axis movable body 7 coincides with the heights of the shaft centers of the X-axis shafts 18A, 18B and X-axis movers 19A, 19B, it is possible to further stabilize and support the X-axis movable body 7 using the X-axis drive part 6, making it possible to move the X-axis movable body 7 without generating pitching.

Further, this embodiment exhibits the following effects. That is, since Y-axis shafts 3A, 3B having magnets inside, and Y-axis movers 9A, 9B comprising coils surrounding these Y-axis shafts 3A, 3B are used as the Y-axis drive part 3 that moves the Y-axis movable body 4, it is possible to make the drive part smaller than a linear motor or the like, and therefore, it is possible to arrange the lateral part 4b of the Y-axis movable body 4 facing the side gliding surface 2d downwardly of the one Y-axis mover 9A, making it possible to eliminate the X-axis direction footprint occupied by the lateral part 4b when lined up side-to-side with the Y-axis drive part 3A. Consequently, it is possible to reduce the footprint of the stage apparatus 1, and to strive to make the apparatus more compact.

Further, the Y-axis yaw air bearing 17, which corresponds to attraction generating means in accordance with a magnet 17c and magnetic body 33, is disposed in the one lateral part of the Y-axis movable body 4, and if a balance is consequently achieved, enabling the apparatus to be made more compact than when a balance is achieved by disposing Y-axis yaw air bearings 17 on both sides.

Further, since the Y-axis yaw air bearing 17 is structured to be supported on the outer side of the lateral part 4b, manufacturing and maintenance are easier than in a structure in which the Y-axis yaw air bearing is embedded on the inner side of the lateral part 4b. In particular, when the Y-axis yaw air bearing 17 is embedded in the support part 16, the air supply duct must pass through the inside of the support part 16, making manufacturing and maintenance difficult, but since the Y-axis yaw air bearing 17 is able to pass the air supply duct through from the outside, manufacturing and maintenance are easy.

Further, even when the precision of the base 2 and Y-axis mobile body 4 are low, and the support part 16 is inclined toward the side gliding surface 2d of the base 2, the repulsive force and attraction force between the side gliding surface 2d and Y-axis yaw are bearing 17 can be balanced while the Y-axis yaw air bearing 17 rotates, and the Y-axis movable body 4 can be moved while properly maintaining the spacing of the gap between the side gliding surface 2d and the Y-axis yaw air bearing 17. According to the above, the base 2 and Y-axis movable body 4 can be readily processed and assembled without the need for processing precision or assembly precision.

Further, since the Y-axis yaw air bearing 17 is supported by way of a spherically-shaped part 29 in the support part 16 constituting the lateral part 4b of the Y-axis movable body 4, it is possible to freely rotate the Y-axis yaw air bearing 17 three-dimensionally around the contact part of the spherically-shaped part 29.

Further, since the Y-axis yaw air bearing 17 is supported by the support part 16 by elasticity being imparted from the expandable spring 32 disposed around the spherically-shaped part 29, it is possible to provide support by bringing the Y-axis yaw air bearing 17 into contact with the spherically-shaped part 29 with optimum force, and when the Y-axis yaw air bearing 17 rotates three-dimensionally around the part that makes contact with the spherically-shaped part 29, the spring 32 expands and contracts to allow this, making it possible to reliably support the support part 16 without impeding the operation of the Y-axis yaw air bearing 17.

The present invention has been explained in detail above based on the embodiment, but the present invention is not limited to the above-described embodiment, and, for example, in the above-described embodiment, the magnet 17c is disposed on the blowing surface 17a side of the Y-axis yaw air bearing 17 and the magnetic body 33 is disposed on the side gliding surface 2d side of the base 2, but the arrangement of the magnet and magnetic body can be reversed.

According to the stage apparatus related to the present invention, it is possible to move the movable body, which is a wafer stage, without generating pitching.

Furthermore, this application relates to and claims the benefit of priority from Japanese Patent Application number 2007-272971 filed on Oct. 19, 2007, the entire disclosure of which is incorporated herein by reference.

What is claimed is:

1. A stage apparatus comprising:
a pair of Y-axis stators, which are fixed to the top surface of a base and extend in a Y-axis direction;
a pair of Y-axis movers that move along the respective the Y-axis stators;
a shaft motor having an X-axis shaft, which extends in an X-axis direction that is orthogonal to the Y-axis direction, and is connected to the pair of Y-axis movers, and an X-axis mover, which is constituted by a coil that surrounds the X-axis shaft; and
a movable body that moves over the base,
wherein the X-axis mover is connected to the side of the movable body.

2. The stage apparatus according to claim 1, wherein the shaft motor is provided in a pair, and the pair of shaft motors are respectively arranged on both outer sides of the movable body.

3. The stage apparatus according to claim 1, further comprising a guidebeam, which is connected to the pair of Y-axis movers, is positioned on the inner side of the movable body, and extends in the X-axis direction,
wherein the movable body has a lateral part, which faces the side of the guidebeam, and a pair of first air bearings, which are disposed on the lateral part and blow air on the side of the guidebeam.

4. The stage apparatus according to claim 1, wherein the movable body has a second air bearing that blows air on the top surface of the base.

5. The stage apparatus according to claim 1, wherein the height of the center of gravity of the movable body coincides with the heights of the shaft centers of the X-axis shaft and the X-axis mover.
